(19) United States
(12) Patent Application Publication
(10) Pub. No.: US 2026/0003295 A1
(43) Pub. Date: Jan. 1, 2026

(54) SCANNING DIFFRACTION-BASED OVERLAY SCATTEROMETRY

(71) Applicant: KLA Corporation, Milpitas, CA (US)

(72) Inventors: Alon Alexander Volfman, Migdal Ha'emek (IL); Itay Gdor, Tel-Aviv (IL); Iftach Galon, Migdal Ha'emek (IL); David Koprivica, Migdal Ha'emek (IL); Yonatan Vaknin, Yoqneam Llit (IL); Vladimir Levinski, Migdal Ha'emek (IL); Yaniv Weiss, Tel Aviv (IL); Yuval Lubashevsky, Haifa (IL); Daria Negri, Nesher (IL); Mark Ghinovker, Yoqneam Ilit (IL)

(21) Appl. No.: 18/755,107

(22) Filed: Jun. 26, 2024

(51) Int. Cl. G03F 7/00

(52) U.S. Cl. CPC G03F 7/70633; G03F 7/70641; G03F 7/706837; G03F 7/706839

(57) ABSTRACT

An overlay metrology system includes a controller communicatively coupled to a first photodetector and a second photodetector. The controller may be configured to receive one or more signals from the first and second photodetector as an overlay target is scanned. The overlay target may include a plurality of measurement cells, where each measurement cell includes a grating-over-grating structure including a first-layer grating feature on a first layer of a sample and a second-layer grating feature on a second layer of the sample in an overlapping region. The first-layer grating feature and the second-layer grating feature may have a common pitch. The controller may be further configured to determine one or more differential signals between the first photodetector and the second photodetector for each measurement cell of the plurality of measurement cells and determine an overlay measurement based on the determined one or more differential signals.

### TECHNICAL FIELD

The present disclosure relates generally to overlay metrology and, more particularly, to scanning diffraction-based overlay scatterometry.

### BACKGROUND

Overlay metrology generally refers to measurements of the relative alignment of layers on a sample such as, but not limited to, semiconductor devices. An overlay measurement, or a measurement of overlay error, typically refers to a measurement of the misalignment of fabricated features on two or more sample layers. In a general sense, proper alignment of fabricated features on multiple sample layers is necessary for proper functioning of the device.

Demands to decrease feature size and increase feature density are resulting in correspondingly increased demand for accurate and efficient overlay metrology. Metrology systems typically generate metrology data associated with a sample by measuring or otherwise inspecting dedicated metrology targets distributed across the sample. Accordingly, the sample is typically mounted on a translation stage and translated such that the metrology targets are sequentially moved into a measurement field of view. In typical metrology systems employing a move and measure (MAM) approach, the sample is static during each measurement and requires many different target location measurements. However, the time required for the translation stage to settle prior to a measurement may impact the throughput. Further, image-based scatterometry overlay techniques require a high sensitivity camera (e.g., CCD camera) that contributes to the cost of the metrology sub-system and requires two separate measurements per direction such that measurement of a single target is time consuming. Existing techniques may further utilize targets having different pitches, however, printing such targets is difficult.

Therefore, it is desirable to provide systems and methods for curing the above deficiencies.

### SUMMARY

An overlay metrology system is disclosed, in accordance with one or more embodiments of the present disclosure. In embodiments, the overlay metrology system includes an illumination sub-system. In embodiments, the illumination sub-system includes one or more illumination sources configured to generate one or more illumination beams. In embodiments, the illumination sub-system includes one or more illumination optics configured to direct the one or more illumination beams to an overlay target on a sample as the sample is scanned along a stage-scan direction by a translation stage when implementing a metrology recipe, where the overlay target in accordance with the metrology recipe includes a plurality of measurement cells, where each measurement cell includes a grating-over-grating structures including a first-layer grating feature on a first layer of the sample and a second-layer grating feature on a second layer of the sample in an overlapping region, where the first-layer grating feature and the second-layer grating feature have a common pitch. In embodiments, the overlay metrology system includes a collection sub-system. In embodiments, the collection sub-system includes a first photodetector located in a pupil plane to collect +1-order diffraction from the overlay target, where the first photodetector does not collect 0-order diffraction from the overlay target. In embodiments, the collection sub-system includes a second photodetector located in a pupil plane to collect −1-order diffraction from the overlay target, where the second photodetector does not collect 0-order diffraction from the overlay target. In embodiments, the collection sub-system includes one or more collection optics. In embodiments, the overlay metrology system includes and a controller communicatively coupled to the first photodetector and the second photodetector, where the controller includes one or more processors configured to execute program instructions causing the one or more processors to: receive one or more signals from the first photodetector and the second photodetector as the overlay target is scanned along the stage-scan direction; determine one or more differential signals between the first photodetector and the second photodetector for each measurement cell of the plurality of measurement cells based on the received one or more signals; and determine an overlay measurement based on the determined one or more differential signals.

An overlay metrology system is disclosed, in accordance with one or more embodiments of the present disclosure. In embodiments, the overlay metrology system includes a controller communicatively coupled to a first photodetector and a second photodetector. In embodiments, the controller includes one or more processors configured to execute program instructions causing the one or more processors to: receive one or more signals from the first photodetector and the second photodetector as an overlay target is scanned along a stage-scan direction by a translation stage when implementing a metrology recipe, where the overlay target in accordance with the metrology recipe includes a plurality of measurement cells, where each measurement cell includes a grating-over-grating structures including a first-layer grating feature on a first layer of a sample and a second-layer grating feature on a second layer of the sample in an overlapping region, where the first-layer grating feature and the second-layer grating feature have a common pitch. In embodiments, the one or more processors are configured to determine one or more differential signals between the first photodetector and the second photodetector for each measurement cell of the plurality of measurement cells based on the received one or more signals. In embodiments, the one or more processors are configured to determine an overlay measurement based on the determined one or more differential signals.

A method is disclosed, in accordance with one or more embodiments of the present disclosure. In embodiments, the method includes illuminating an overlay target with a plurality of measurement cells on a sample having grating-over-grating structures as the sample is translated along a stage-scan direction with an illumination beam. In embodiments, the method includes receiving one or more signals from a first photodetector and a second photodetector as the overlay target is scanned along the stage-scan direction by a translation stage when implementing a metrology recipe, where the overlay target in accordance with the metrology recipe includes a plurality of measurement cells, where each measurement cell includes a grating-over-grating structures including a first-layer grating feature on a first layer of the sample and a second-layer grating feature on a second layer of the sample in an overlapping region, where the first-layer grating feature and the second-layer grating feature have a common pitch. In embodiments, the method includes determining one or more differential signals between the first photodetector and the second photodetector for each measurement cell of the plurality of measurement cells based on the received one or more signals. In embodiments, the method includes determining an overlay measurement based on the determined one or more differential signals.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures in which:

FIG. 1A illustrates a conceptual view of a system for performing scanning diffraction-based overlay scatterometry metrology, in accordance with one or more embodiments of the present disclosure.

FIG. 1B illustrates a schematic view of the overlay metrology sub-system, in accordance with one or more embodiments of the present disclosure.

FIG. 2 illustrates a side view of a measurement cell of the overlay target, in accordance with one or more embodiments of the present disclosure.

FIG. 3A illustrates a top view of an illumination pupil in an illumination pupil plane of the overlay metrology sub-system, in accordance with one or more embodiments of the present disclosure.

FIG. 3B illustrates a top view of an illumination pupil in an illumination pupil plane of the overlay metrology sub-system, in accordance with one or more embodiments of the present disclosure.

FIG. 3C illustrates a top view of an illumination pupil in an illumination pupil plane of the overlay metrology sub-system, in accordance with one or more embodiments of the present disclosure.

FIG. 3D illustrates a top view of a collection pupil in the collection pupil plane of the overlay metrology sub-system, in accordance with one or more embodiments of the present disclosure.

FIG. 3E illustrates a top view of a collection pupil in the collection pupil plane of the overlay metrology sub-system, in accordance with one or more embodiments of the present disclosure.

FIG. 3F illustrates a top view of a collection pupil in the collection pupil plane of the overlay metrology sub-system, in accordance with one or more embodiments of the present disclosure.

FIG. 4A illustrates a plot of a signal, in accordance with one or more embodiments of the present disclosure.

FIG. 4B illustrates a plot of a signal, in accordance with one or more embodiments of the present disclosure.

FIG. 5 illustrates a flow diagram illustrating a method for performing scanning diffraction-based overlay metrology, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to diffraction-based overlay (DBO) scanning scatterometry metrology. For example, the DBO scanning scatterometry metrology may measure overlay of overlay metrology targets having grating-over-grating features with a common pitch. For example, the overlay metrology target may include a plurality of cells including a grating-over-grating structure formed from overlapping regions of periodic structures on two or more sample layers that is illuminated with an illumination beam having a limited angular extent to generate discrete diffraction orders. The two or more photodetectors may detect signals from the overlay metrology target associated with positive and negative diffraction in a collection pupil generated as the grating-over-grating structure is scanned through an illumination beam. In embodiments, illumination and collection conditions are configured such only first-order diffraction (e.g., +/−1 diffraction orders) is collected. In this regard, the 0-order diffraction and first-order diffraction (e.g., +/−1 diffraction orders) do not overlap in a collection pupil plane. Differential signals between the two or more photodetectors for each cell of the plurality of cells may then be generated, such that an overlay measurement may be generated based on the respective differential signals.

For the purposes of the present disclosure, the term scatterometry metrology is used to broadly encompass the terms scatterometry-based metrology and diffraction-based metrology in which a sample having periodic features on one or more sample layers is illuminated with an illumination beam having a limited angular extent and one or more distinct diffraction orders are collected for the measurement. Further, the term scanning metrology is used to describe metrology measurements generated when samples are in motion. In a general sense, scanning metrology may be implemented by scanning a sample along a measurement path (e.g., a swath, or the like) such that regions of interest on the sample (e.g., metrology targets, device areas, or the like) are translated through a measurement field of view of a metrology system. Further, the process may be repeated for any number of measurement paths or repeated measurements of particular measurement paths to provide any desired number of measurements of the sample.

It is contemplated herein that, regardless of the particular intensity profile, the symmetry between positive and negative diffraction orders (e.g., +/−1 diffraction orders) may also be influenced by various characteristics of the grating-over-grating structures. For example, asymmetries in the grating-over-grating structure such as, but not limited to, the relative alignment of the grating features in the various layers, may manifest as asymmetries between positive and negative diffraction orders. As an illustration, a fully symmetric grating-over-grating structure may generate symmetric positive and negative diffraction orders. In contrast, sample asymmetries such as overlay errors may induce asymmetries between various aspects of the positive and negative diffraction orders such as, but not limited to, the relative intensity or phase between the positive and negative diffraction orders.

As a result, metrology measurements of asymmetries of the grating-over-grating structures such as overlay measurements may be generated based on comparisons of positive and negative diffraction orders. For example, scatterometry overlay based on pupil-plane images of diffraction orders of static samples is described generally in U.S. Pat. No. 10,824,079, issued on Nov. 3, 2020; U.S. Pat. No. 10,197,389, issued on Feb. 5, 2019; and U.S. Pat. No. 11,119,417, issued on Sep. 14, 2021, which is incorporated herein by reference in its entirety. In this publication, phase shifts associated with an overlay measurement between +1 and −1 diffraction orders are determined through an analysis of at least one pupil-plane image in which a −1-diffraction order and a +1-diffraction order are spatially separated in the pupil plane.

However, it is further contemplated herein that techniques based on pupil-plane images of static samples may have limited measurement throughput based at least in part on the time required to start and stop a translation stage when positioning an overlay target or other portion of the sample for a measurement.

It is further contemplated herein that the systems and methods disclosed herein may provide sensitive overlay metrology at a high throughput. For example, the non-imaging configuration enables the use of fast photodetectors suitable for fast scan speeds. As a non-limiting example, photodetectors having a bandwidth of 1 GHz may enable scan speeds of approximately 10 centimeters per second on grating-over-grating targets having a pitch of 1 micrometer.

Some embodiments of the present disclosure are directed to providing recipes for configuring an overlay metrology sub-system. An overlay metrology sub-system is typically configurable according to a recipe including a set of parameters for controlling various aspects of an overlay measurement such as, but not limited to, the illumination of a sample, the collection of light from the sample, or the position of the sample during a measurement. In this way, the overlay metrology sub-system may be configured to provide a selected type of measurement for one or more overlay target designs of interest. For example, a metrology recipe may include illumination parameters such as, but not limited to, a number of illumination beams, an illumination wavelength, an illumination pupil distribution (e.g., a distribution of illumination angles and associated intensities of illumination at those angles), a polarization of incident illumination, or a spatial distribution of illumination. By way of another example, a metrology recipe may include collection parameters such as, but not limited to, a collection pupil distribution (e.g., a desired distribution of angular light from the sample to be used for a measurement and associated filtered intensities at those angles), collection field stop settings to select portions of the sample of interest, polarization of collected light, wavelength filters, positions of one or more detectors (e.g., photodetectors) or parameters for controlling the one or more detectors. By way of a further example, a metrology recipe may include various parameters associated with the sample position during a measurement such as, but not limited to, a sample height, a sample orientation, whether a sample is static during a measurement, or whether a sample is in motion during a measurement (along with associated parameters describing the speed, scan pattern, or the like).

The grating-over-grating features suitable for generating the diffraction patterns of interest may generally be located anywhere on the sample. In embodiments, overlay metrology may be performed directly on device features having suitable geometries. By way of another example, overlay metrology may be performed on dedicated overlay targets, which may be located at any suitable locations such as, but not limited to, within dies or within scribe lines between dies. In this way, overlay measurements on overlay targets may be representative of the overlay of device features. Dedicated overlay targets may generally include features that are designed to provide accurate overlay measurements based on a particular overlay measurement technique. Further, overlay targets may include one or more measurement cells, where each cell includes printed elements in overlapping regions of one or more layers on the sample. An overlay measurement may then be based on any combination of measurements of the various cells of the overlay target. For example, multiple cells of an overlay target may be designed with different intended offsets (e.g., grating structures in the various layers of the sample that are intentionally misaligned with known offset values), which may improve the accuracy and/or sensitivity of the measurement.

It is contemplated herein that scanning DBO scatterometry metrology as disclosed herein may provide numerous benefits. For example, the capability to capture measurement signals indicative of overlay as a sample is scanned may avoid stage acceleration and deceleration times required to capture an image of a static target and may thus provide relatively high measurement throughput. In this way, the number of overlay measurements in a given time period may be substantially increased.

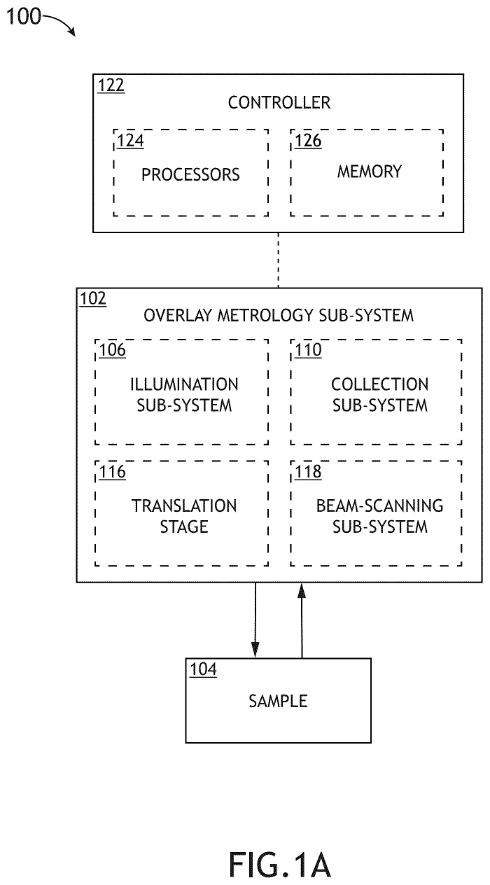

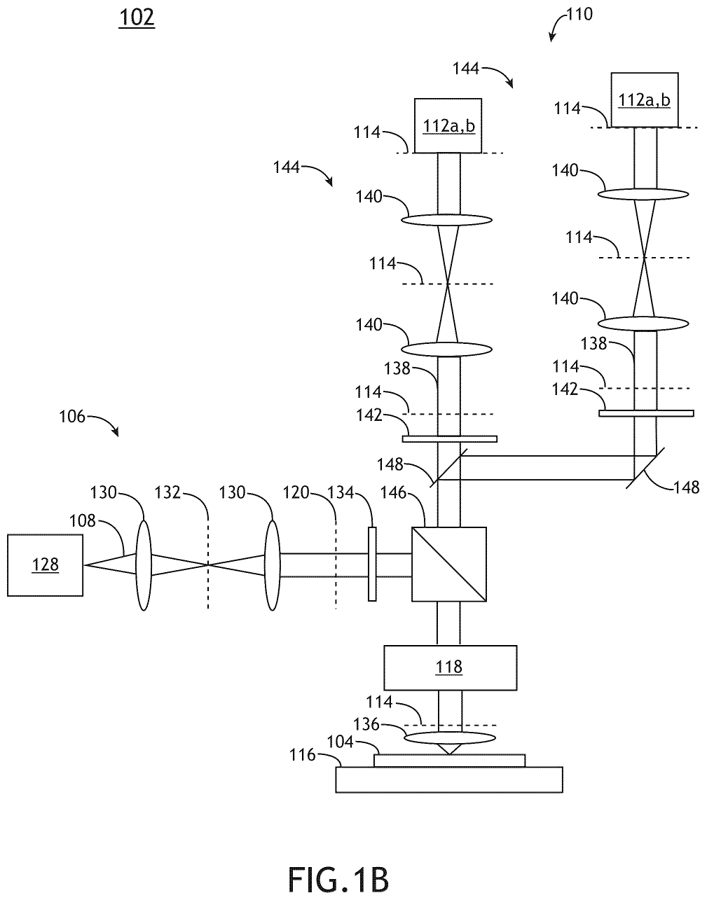

Referring now to FIGS. 1A-5, systems and methods for scanning DBO scatterometry metrology are described in greater detail in accordance with one or more embodiments of the present disclosure.

FIG. 1A illustrates a conceptual view of a system 100 for performing scanning DBO scatterometry metrology, in accordance with one or more embodiments of the present disclosure.

In embodiments, the system 100 includes an overlay metrology sub-system 102 to perform scatterometry-based overlay measurements on sample 104. For example, the overlay metrology sub-system 102 may perform scatterometry-based overlay measurements on portions of the sample 104 having grating-over-grating structures such as, but not limited to, dedicated overlay targets. In embodiments, the overlay metrology sub-system includes an illumination sub-system 106, a collection sub-system 110, a translation stage 116, and a beam-scanning sub-system 118. In embodiments, the system 100 includes a controller 122. The controller 122 includes one or more processors 124 and memory 126.

The one or more processors 124 may be configured to execute a set of program instructions maintained in the memory device 126. For example, the one or more processors 124 may be configured to receive one or more signals from two or more photodetectors as an overlay target is scanned along a stage-scan direction by the translation stage 116 when implementing a metrology recipe. By way of another example, the one or more processors 124 may be configured to determine one or more differential signals between the two or more photodetectors for each measurement cell of the plurality of measurement cells based on the received one or more signals. By way of another example, the one or more processors 124 may be configured to determine an overlay measurement based on the determined one or more differential signals.

FIG. 1B illustrates a simplified schematic view of the overlay metrology sub-system 102, in accordance with one or more embodiments of the present disclosure.

In embodiments, the illumination sub-system 106 to generate illumination in the form of one or more illumination beams 108 to illuminate the sample 104 and the collection sub-system 110 to collect light from the illuminated sample 104. For example, the one or more illumination beams 108 may be angularly limited on the sample 104 such that grating-over-grating structures (e.g., in one or more cells of an overlay target) may generate discrete diffraction orders. Further, the one or more illumination beams 108 may be spatially limited such that they may illuminate selected portions of the sample 104. For instance, each of the one or more illumination beams 108 may be spatially limited to illuminate a particular cell of an overlay target.

The collection sub-system 110 may then collect +/−1 diffraction orders from the sample 104 associated with diffraction of the illumination beam 108. Further, the collection sub-system 110 may include at least two photodetectors 112a,b positioned in a collection pupil plane 114 to capture only the +/−1 diffraction orders.

In embodiments, the translation stage 116 to scan the sample 104 through a measurement field of view of the overlay metrology sub-system 102 during a measurement to implement scanning metrology.

In embodiments, the beam-scanning sub-system 118 configured to modify or otherwise control a position of at least one illumination beam 108 on the sample 104. For example, the beam-scanning sub-system 118 may scan an illumination beam 108 in a direction orthogonal to a scan direction (e.g., a direction in which the translation stage 116 scans the sample 104) during a measurement.

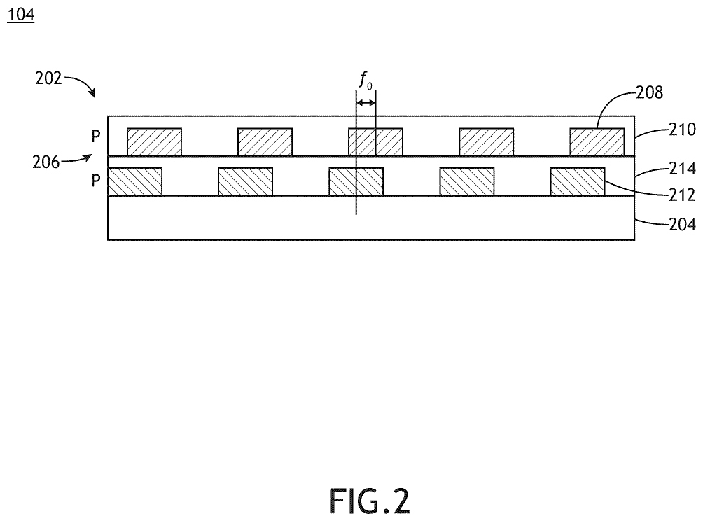

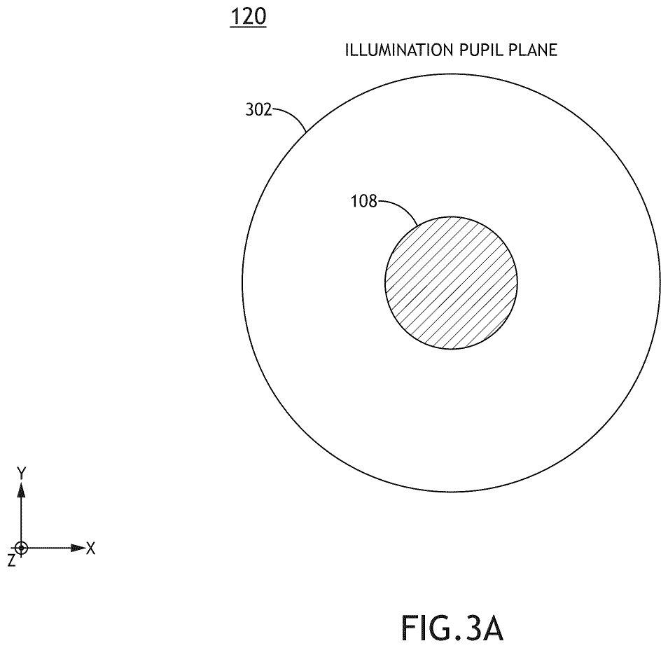

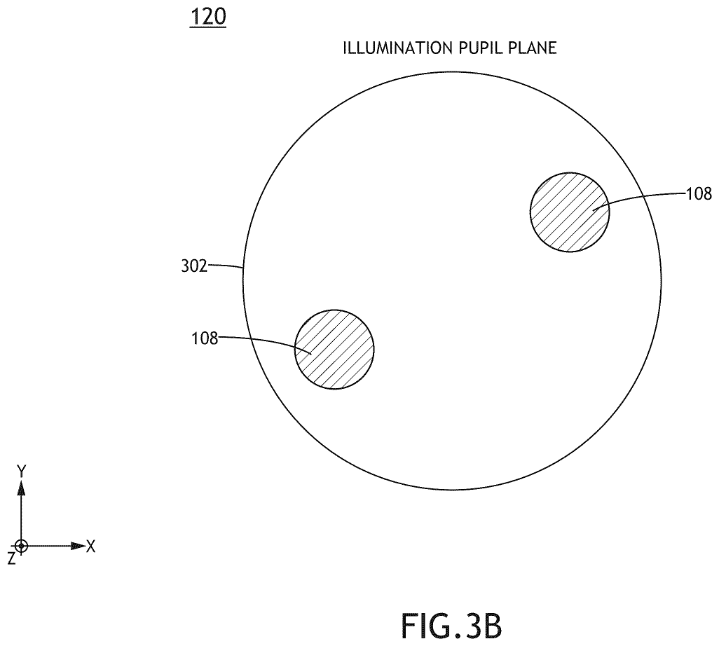

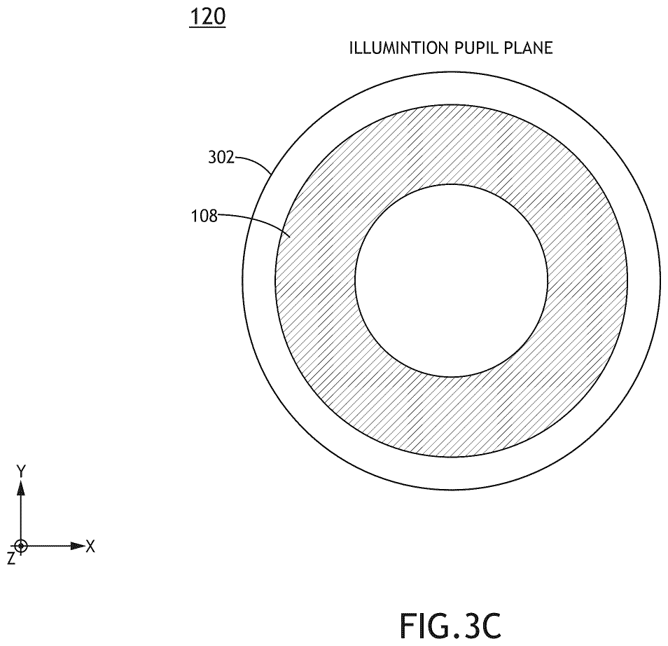

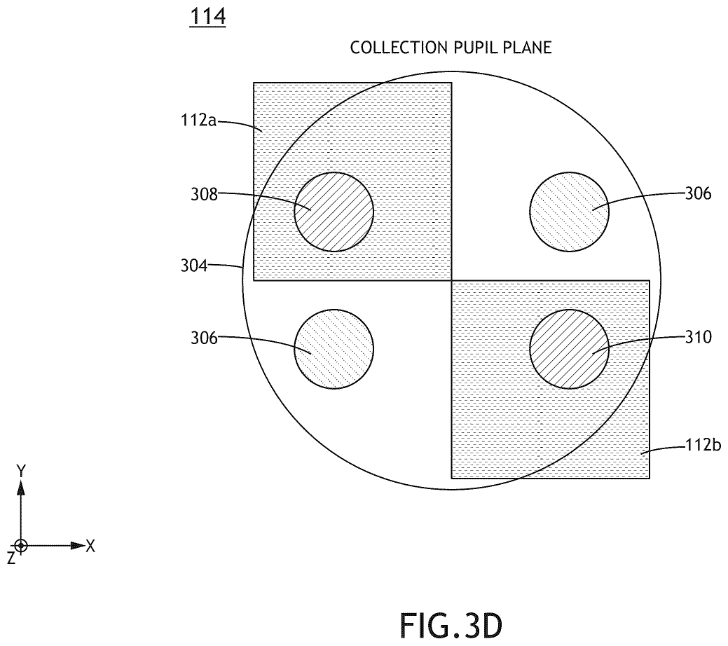

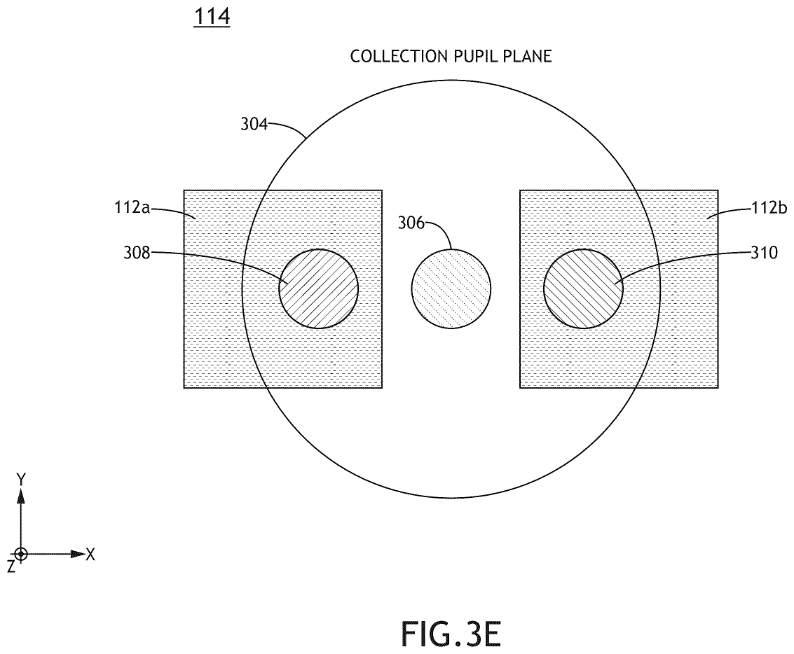

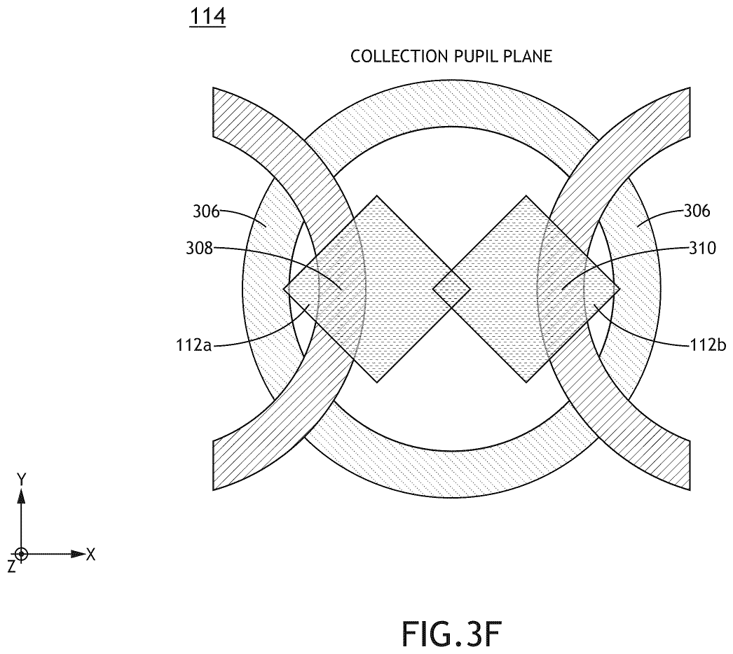

Referring now to FIGS. 2-3D, the collection of diffraction orders from grating-over-grating structures and the placement of the photodetectors 112a,b for scanning scatterometry overlay metrology is described in greater detail in accordance with one or more embodiments of the present disclosure.

FIG. 2 illustrates a side view of a cell 204 of an overlay target 202, in accordance with one or more embodiments of the present disclosure.

In embodiments, the overlay target 202 includes the plurality of measurement cells 204, where any particular measurement cell 204 may include a grating structure 206 with a periodicity along any direction.

In embodiments, the grating structure 206 includes two or more diffraction gratings. For example, the grating structure 206 may include a first structure 208 (e.g., first-layer grating feature 208) located on a first layer 210 of the sample 104 and second structure 212 (e.g., second-layer grating feature 212) located on a second layer 214 of the sample 104. For instance, the grating structure 206 may include a grating-over-grating structure, where the first structure 208 and the second structure 212 are overlapping.

In embodiments, the first structure 208 and the second structure 212 have the same pitches. For example, in a non-limiting example depicted in FIG. 2, the pitches of the first structure 208 and the second structure 212 may be P. As previously discussed herein, it is noted herein that some existing scanning techniques utilize targets having different pitches. It is contemplated herein, that due to design rules, it is in some cases impossible to print grating-over-grating structures with different pitches (e.g., overlapping structures having different pitches), especially in cut mask process layers. As such, it is advantageous for the overlay target 202 to include features having a common pitch.

Further, it is contemplated herein that the configuration depicted in FIG. 2 is provided merely for illustrative purposes and shall not be construed as limiting the scope of the present disclosure. As such, the grating structure 206 may be formed of any number of layers with any variety of pitches. For example, the grating structure 206 may be formed of two or more layers.

It is to be understood that the overlay target 202 in FIG. 2 and the associated description are provided solely for illustrative purposes and should not be interpreted as limiting. Rather, the overlay target 202 may include any suitable grating-over-grating overlay target design. For example, the overlay target 202 may include any number of cells 204 suitable for measurements along two directions. For instance, to measure overlay in the x- or y-direction, the overlay target 202 may include two cells with opposite intended offsets (f₀). In this regard, a first cell may have an intended offset +f₀ and a second cell may have an intended offset −f₀. Further, the cells 204 may be distributed in any pattern or arrangement. For example, metrology target designs suitable for scanning metrology are generally described in U.S. Pat. No. 11,073,768, issued on Jul. 27, 2021, which is incorporated herein by reference in its entirety.

FIGS. 3A-3C illustrate top views of an illumination pupil 302 in an illumination pupil plane 120 of the overlay metrology sub-system 102, in accordance with one or more embodiments of the present disclosure. For example, the illumination pupil plane 120 may correspond to a pupil plane in the illumination sub-system 106 as illustrated in FIG. 1B. FIGS. 3D-3F are top views of a collection pupil 304 in the collection pupil plane 114 of the overlay metrology sub-system 102, in accordance with one or more embodiments of the present disclosure. For example, the collection pupil plane 114 may correspond to a pupil plane 114 in the collection sub-system 110 as illustrated in FIG. 1B.

In embodiments, the illumination sub-system 106 illuminates the overlay target 202 with one or more illumination beams 108 at normal incidence (or near-normal incidence) as illustrated in FIG. 3A. Further, the one or more illumination beams 108 may illuminate the overlay target 202 with a limited range of incidence angles as illustrated by the limited size in the collection pupil plane 114. In this regard, the overlay target 202 may diffract the one or more illumination beams 108 into discrete diffraction orders. In embodiments, the illumination sub-system 106 illuminates the overlay target 202 with one or more illumination beams 108 at non-normal incidence as illustrated in FIGS. 3B-3C.

FIGS. 3D-3F illustrate a distribution of 0-order diffraction 306, +1-order diffraction 308, and −1-order diffraction 310 distributed along the direction of periodicity of the grating-over-grating structure (e.g., the X direction here) in the collection pupil plane 114. In particular, the +1-order diffraction 308 and the −1-order diffraction 310 are distributed on opposite sides of the 0-order diffraction 306.

In embodiments, the illumination sub-system 106, the collection sub-system 110, and the overlay target 202 are configured to provide that the first-order diffraction (e.g., the +1-order diffraction 308 and the −1-order diffraction 310) does not overlap with the 0-order diffraction 306. For example, as illustrated in FIGS. 3D-3F, the −1-order diffraction 310 does not overlap with the 0-order diffraction 306 and the +1-order diffraction 308 does not overlap with the 0-order diffraction 306. In this regard, only the first-order diffraction (e.g., the +1-order diffraction 308 and the −1-order diffraction 310) are collected by the collection sub-system 110.

In embodiments, the overlay metrology sub-system 102 includes photodetectors 112a,b located in the collection pupil plane 114 to only capture the first-order diffraction (e.g., the +1-order diffraction 308 and the −1-order diffraction 310). For example, as illustrated in FIGS. 3D-3F, a first photodetector 112a is located in the collection pupil plane to capture the +1-order diffraction 308 and a second photodetector 112b is located in the collection pupil plane 114 to capture the −1-order diffraction 310, where the first photodetector 112a and the second photodetector 112b do not collect the 0-order diffraction. Each of the photodetectors 112a,b may then capture a signal as the sample 104 is scanned. In particular, as the overlay target 202 is scanned along a direction of periodicity of the grating-over-grating structure the phase of the +/−1 diffraction orders 308, 310 relative to the 0-order diffraction 306 shifts in opposite directions.

It is recognized herein that the distribution of diffracted orders of an illumination beam 108 by a periodic structure such as a grating-over-grating structure may be influenced by a variety of parameters such as, but not limited to, a wavelength of the illumination beam 108, an incidence angle of the illumination beam 108 in both altitude and azimuth directions, a period of the periodic structures, or a numerical aperture (NA) of a collection lens. Accordingly, in embodiments of the present disclosure, the illumination sub-system 106, the collection sub-system 110, and the overlay target 202 may be configured (e.g., according to a metrology recipe defining a selected set of associated parameters) to provide distribution first-order diffraction in the collection pupil plane 114 of the collection sub-system 110. For example, the illumination sub-system 106 and/or the collection sub-system 110 may be configured to generate measurements on grating-over-grating structures having a selected range of periodicities. Further, various components of the illumination sub-system 106 and/or the collection sub-system 110 (e.g., stops, pupils, or the like) may be adjustable to provide distribution for a given grating-over-grating structure with a given periodicity.

It is contemplated herein that multi-directional measurements may be obtained using a variety of techniques, for example, as generally discussed in U.S. Pat. No. 11,300,405, issued on Apr. 12, 2022, which is herein incorporated by reference in the entirety. In embodiments, the overlay target may includes two sets of cells, where a first set of cells includes grating-over-grating structures oriented along a first diagonal direction different than but not orthogonal to a scan direction, and where a second set of cells includes grating-over-grating structures oriented along a second diagonal direction orthogonal to the first diagonal direction. In this way, overlay measurements along the first and second diagonal directions may be generated during a scan. Further, the scan may be implemented by translating the sample through a measurement field and/or by translating one or more illumination beams. In embodiments, a sample is scanned by a translation stage along a stage-scan direction and one or more illumination beams are scanned along a beam-scan direction that may be orthogonal to the stage-scan direction. In this configuration, an overlay target may include two sets of cells, where a first set of cells includes grating-over-grating structures oriented along the stage-scan direction, and where a second set of cells includes grating-over-grating structures oriented along the beam-scan direction.

In embodiments, the signals of a first cell are collected by a first photodetector and the signals of a second cell are collected by a second photodetector. For example, in a non-limiting example, four signals may be acquired. For instance, a first signal (S₁) of the first cell associated with +1-order diffraction 308 may be collected by the first photodetector 112a, a second signal (S₂) of the first cell associated with −1-order diffraction 310 may be collected by the second photodetector 112b, a third signal (S₃) of the second cell associated with +1-order diffraction 308 may be collected by the first photodetector 112a, and a fourth signal (S₄) of the second cell associated with −1-order diffraction 310 may be collected by the second photodetector 112b.

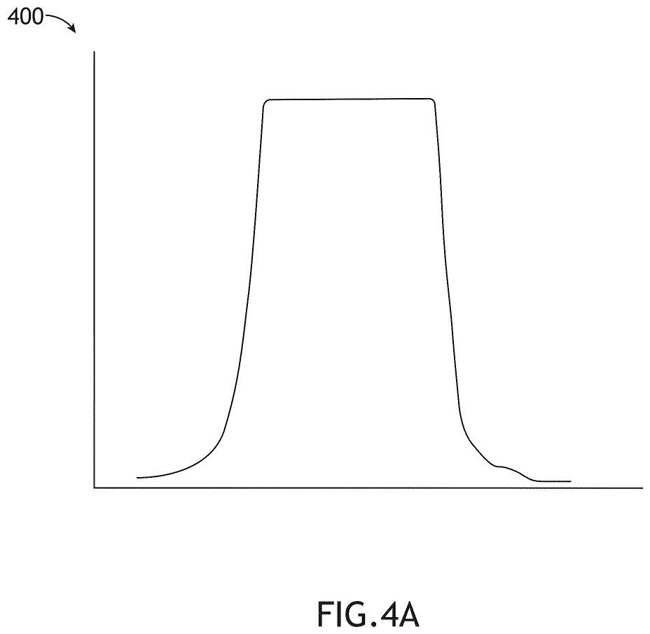

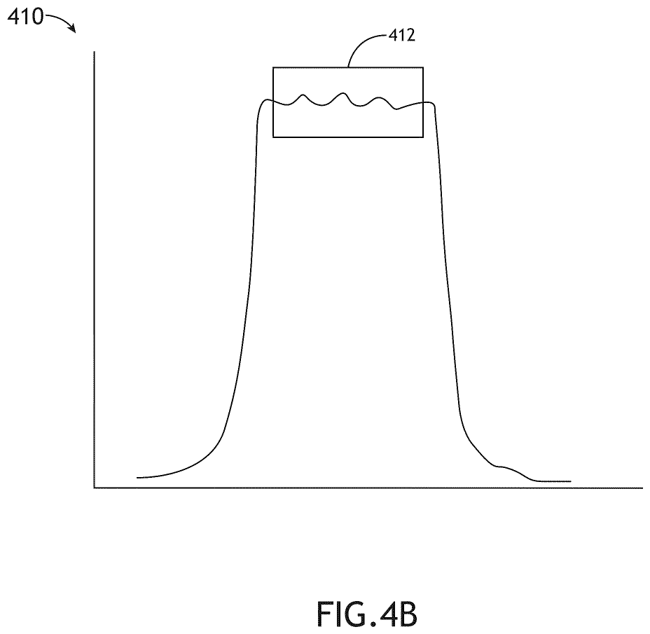

In embodiments, each of the one or more signals (S₁-S₄) may be constant intensity signals collected by the two or more photodetectors. For example, as shown in FIG. 4A, the one or more signals of plot 400 may not oscillate, such that the intensity signal is constant over a select period of time. In embodiments, the one or more signals (S₁-S₄) may oscillate. For example, as shown in FIG. 4B, the one or more signals of plot 410 may oscillate over a select period of time, where a region of interest (ROI) 412 is selected. Once the ROI 412 has been selected, one or more data processing models (or algorithms) may be applied to determine one or more post-processing signals. For instance, part of the waveplan within the ROI 412 may be used during post-processing of the one or more signals (S₁-S₄). It is contemplated herein that the one or more data processing steps may include any type of data processing step including, but not limited to, determining an average signal, weighted average signal, running average signal, or the like.

To measure overlay in the x- or y-direction, two cells with opposite intentional shifts (f₀) may be used. In each cell, a differential signal D may be calculated based on the signals. For example, differential signal (D₁) for the first cell may be calculated according to Eq. (1.1), as shown and described below:

$${D}_{1} = {S}_{1} - {S}_{2} \qquad Eq . ( 1.1 )$$

By way of another example, differential signal (D₂) for the second cell may be calculated according to Eq. (1.2), as shown and described below:

$${D}_{2} = {S}_{3} - {S}_{4} \qquad Eq . ( 1.2 )$$

Accordingly, overlay (OVL) may be measured according to at least one of Eqs. (2.1) or (2.2) as shown and described below:

$$OVL = \frac{P}{2 π} arctan ( \frac{D 1 + D 2}{D 1 - D 2} tan ( \frac{2 π}{P} {f}_{0} ) ) \qquad Eq . ( 2.1 )$$

$$OVL = {f}_{0} \frac{D 1 + D 2}{D 1 - D 2} \qquad Eq . ( 2.2 )$$

where P is the pitch of the first-layer grating feature and the second-layer grating feature and f₀ is the intended offset.

The photodetectors 112a,b may generally include any type of optical detector known in the art suitable for capturing signals generated as the sample 104 is translated by the translation stage 116 and/or as one or more illumination beams 108 are scanned by the beam-scanning sub-system 118. For example, the photodetectors 112a,b may include, but are not limited to, fast photodiodes. For instance, a non-limiting example, the fast photodiodes may include two fast diodes per direction (i.e., a four-diode detector), where each diode collects signal from ±1-order diffractions.

In a general sense, the bandwidth of the photodetectors 112a,b, the translation speed along the measurement direction, and the pitch of the grating-over-grating structures may be selected together to provide a desired sampling rate of the signals.

Referring again to FIG. 1A, additional components of the overlay metrology sub-system 102 are described in greater detail in accordance with one or more embodiments of the present disclosure.

The one or more processors 124 of the controller 122 may generally include any processor or processing element known in the art. For the purposes of the present disclosure, the term “processor” or “processing element” may be broadly defined to encompass any device having one or more processing or logic elements (e.g., one or more micro-processor devices, one or more application specific integrated circuit (ASIC) devices, one or more field programmable gate arrays (FPGAs), or one or more digital signal processors (DSPs)). In this sense, the one or more processors 124 may include any device configured to execute algorithms and/or instructions (e.g., program instructions stored in memory). In one embodiment, the one or more processors 124 may be embodied as a desktop computer, mainframe computer system, workstation, image computer, parallel processor, networked computer, or any other computer system configured to execute a program configured to operate or operate in conjunction with the system 100, as described throughout the present disclosure. Moreover, different subsystems of the system 100 may include a processor or logic elements suitable for carrying out at least a portion of the steps described in the present disclosure. Therefore, the above description should not be interpreted as a limitation on the embodiments of the present disclosure but merely as an illustration. Further, the steps described throughout the present disclosure may be carried out by a single controller or, alternatively, multiple controllers. Additionally, the controller 122 may include one or more controllers housed in a common housing or within multiple housings. In this way, any controller or combination of controllers may be separately packaged as a module suitable for integration into metrology system 100. Further, the controller 122 may analyze or otherwise process data received from the photodetectors 112a,b and feed the data to additional components within the system 100 or external to the system 100.

Further, the memory device 126 may include any storage medium known in the art suitable for storing program instructions executable by the associated one or more processors 124. For example, the memory device 126 may include a non-transitory memory medium. As an additional example, the memory device 126 may include, but is not limited to, a read-only memory, a random-access memory, a magnetic or optical memory device (e.g., disk), a magnetic tape, a solid-state drive and the like. It is further noted that memory device 126 may be housed in a common controller housing with the one or more processors 124.

In this regard, the controller 122 may execute any of various processing steps associated with overlay metrology. For example, the controller 122 may be configured to generate control signals to direct or otherwise control the overlay metrology sub-system 102, or any components thereof. For instance, the controller 122 may be configured to direct the translation stage 116 to translate the sample 104 along one or more measurement paths, or swaths, to scan one or more overlay targets through a measurement field of view of the overlay metrology sub-system 102 and/or direct the beam-scanning sub-system 118 to position or scan one or more illumination beams 108 on the sample 104. By way of another example, the controller 122 may be configured to receive signals from the photodetectors 112a,b. By way of another example, the controller 122 may generate correctables for one or more additional fabrication sub-systems as feedback and/or feed-forward control of the one or more additional fabrication sub-systems based on overlay measurements from the overlay metrology sub-system 102.

In embodiments, the controller 122 captures the signals detected by the photodetectors 112a,b. The controller 122 may generally capture data using any suitable technique known. Further, the controller 122 may capture the signals, or any data associated with the signals, using any combination of hardware (e.g., circuitry) or software techniques. For example, as shown in FIG. 4A, the one or more signals may not oscillate, such that the intensity signal is constant over a select period of time. By way of another example, as shown in FIG. 4B, the one or more signals of plot 410 may oscillate over a select period of time, where a region of interest (ROI) 412 is selected. Once the ROI 412 has been selected, one or more data processing models (or algorithms) may be applied to determine one or more post-processing signals. For instance, part of the waveplan within the ROI 412 may be used during post-processing of the one or more signals (S₁-S₄). It is contemplated herein that the one or more data processing steps may include any type of data processing step including, but not limited to, determining an average signal, weighted average signal, running average signal, or the like.

In embodiments, the controller 122 determines an overlay measurement based on differential signals between the two or more photodetectors 112a,b. For example, the controller 122, using Eq. (1.1)-(1.2) described above, may be configured to determine one or more differential signals between the two or more photodetectors 112a,b. Further, the controller 122, using at least one of Eqs. (2.1) or (2.2) described above, may be configured to determine overlay based on the determined differential signals.

Referring again to FIG. 1B, various components of the overlay metrology sub-system 102 are described in greater detail in accordance with one or more embodiments of the present disclosure.

In embodiments, the illumination sub-system 106 includes an illumination source 128 configured to generate at least one illumination beam 108. The illumination from the illumination source 128 may include one or more selected wavelengths of light including, but not limited to, ultraviolet (UV) radiation, visible radiation, or infrared (IR) radiation.

The illumination source 128 may include any type of illumination source suitable for providing at least one illumination beam 108. In embodiments, the illumination source 128 is a laser source. For example, the illumination source 128 may include, but is not limited to, one or more narrowband laser sources, a broadband laser source, a supercontinuum laser source, a white light laser source, or the like. In this regard, the illumination source 128 may provide an illumination beam 108 having high coherence (e.g., high spatial coherence and/or temporal coherence). In embodiments, the illumination source 128 includes a laser-sustained plasma (LSP) source. For example, the illumination source 128 may include, but is not limited to, a LSP lamp, a LSP bulb, or a LSP chamber suitable for containing one or more elements that, when excited by a laser source into a plasma state, may emit broadband illumination.

In embodiments, the illumination sub-system 106 includes one or more optical components suitable for modifying and/or conditioning the illumination beam 108 as well as directing the illumination beam 108 to the sample 104. For example, the illumination sub-system 106 may include one or more illumination lenses 130 (e.g., to collimate the illumination beam 108, to relay an illumination pupil plane 120 and/or an illumination field plane 132, or the like). In embodiments, the illumination sub-system 106 includes one or more illumination control optics 134 to shape or otherwise control the illumination beam 108. For example, the illumination control optics 134 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

In embodiments, the overlay metrology sub-system 102 includes an objective lens 136 to focus the illumination beam 108 onto the sample 104 (e.g., an overlay target 202 with overlay target elements located on two or more layers of the sample 104).

In embodiments, the illumination sub-system 106 illuminates the sample 104 with two or more illumination beams 108. Further, the two or more illumination beams 108 may be, but are not required to be, incident on different portions of the sample 104 (e.g., different cells of an overlay target) within a measurement field of view (e.g., a field of view of the objective lens 136). It is contemplated herein that the two or more illumination beams 108 may be generated using a variety of techniques. In embodiments, the illumination sub-system 106 includes two or more apertures at an illumination field plane 132. In embodiments, the illumination sub-system 106 includes one or more beamsplitters to split illumination from the illumination source 128 into the two or more illumination beams 108. In embodiments, at least one illumination source 128 generates two or more illumination beams 108 directly. In a general sense, each illumination beam 108 may be considered to be a part of a different illumination channel regardless of the technique in which the various illumination beams 108 are generated.

In embodiments, the collection sub-system 110 includes at least two photodetectors 112a,b located at a collection pupil plane 114 configured to capture light from the sample 104 (e.g., collected light 138), where the collected light 138 includes the +1-order diffraction 308 and the −1-order diffraction 310, as illustrated in FIGS. 3D-3F. The collection sub-system 110 may include one or more optical elements suitable for modifying and/or conditioning the collected light 138 from the sample 104. In embodiments, the collection sub-system 110 includes one or more collection lenses 140 (e.g., to collimate the illumination beam 108, to relay pupil and/or field planes, or the like), which may include, but are not required to include, the objective lens 136. In embodiments, the collection sub-system 110 includes one or more collection control optics 142 to shape or otherwise control the collected light 138. For example, the collection control optics 142 may include, but are not limited to, one or more field stops, one or more pupil stops, one or more polarizers, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

In embodiments, the collection sub-system 110 includes one or more collection channels 144. For example, as shown in FIG. 1B the collection sub-system 110 may include two or more collection channels 144, each with a separate pair of photodetectors 112a,b. For instance, as illustrated in FIG. 1B, the overlay metrology sub-system 102 may include one or more beamsplitters 146, 148 arranged to split the collected light 138 into the collection channels 144. Further, the beamsplitters 146, 148 may be polarizing beamsplitters, non-polarizing beamsplitters, or a combination thereof. By way of another example, the collection sub-system 110 may include a single collection channel 144.

In embodiments, multiple collection channels 144 are configured to collect light from multiple illumination beams 108 on the sample 104. For example, in the case that an overlay target 202 has two or more cells 204 distributed in a direction different than a scan direction, the overlay metrology sub-system 102 may simultaneously illuminate the different cells 204 with different illumination beams 108 and simultaneously capture signals associated with each illumination beam 108. Additionally, in some embodiments, multiple illumination beams 108 directed to the sample 104 may have different polarizations. In this way, the diffraction orders associated with each of the illumination beams 108 may be separated. For example, polarizing beamsplitters 146 may efficiently separate the diffraction orders associated with the different illumination beams 108. By way of another example, polarizers may be used in one or more collection channels 144 to isolate desired diffraction orders for measurement.

In embodiments, the overlay metrology sub-system 102 includes a beam-scanning sub-system 118 to position, scan, or modulate positions of one or more illumination beams 108 on the sample 104 during measurement.

The beam-scanning sub-system 118 may include any type or combination of elements suitable for scanning positions of one or more illumination beams 108. In one embodiment, the beam-scanning sub-system 118 includes one or more deflectors suitable for modifying a direction of an illumination beam 108. For example, a deflector may include, but is not limited to, a rotatable mirror (e.g., a mirror with adjustable tip and/or tilt). Further, the rotatable mirror may be actuated using any technique known in the art. For example, the deflector may include, but is not limited to, a galvanometer, a piezo-electric mirror, or a micro-electro-mechanical system (MEMS) device. By way of another example, the beam-scanning sub-system 118 may include an electro-optic modulator, an acousto-optic modulator, or the like.

The deflectors may further be positioned at any suitable location in the overlay metrology sub-system 102. In embodiments, one or more deflectors are placed at one or more pupil planes common to both the illumination sub-system 106 and the collection sub-system 110. In this regard, the beam-scanning sub-system 118 may be a pupil-plane beam scanner and the associated deflectors may modify the positions of one or more illumination beams 108 on the sample 104 without impacting positions of diffraction orders in the collection pupil plane 114. Further, a distribution of one or more illumination beams 108 in an illumination field plane 132 may further be stable as the beam-scanning sub-system 118 modifies positions of the one or more illumination beams 108 on the sample 104. Pupil-plane beam scanning is described generally in U.S. Pat. No. 11,300,524, issued on Apr. 12, 2022, which is incorporated by reference in its entirety.

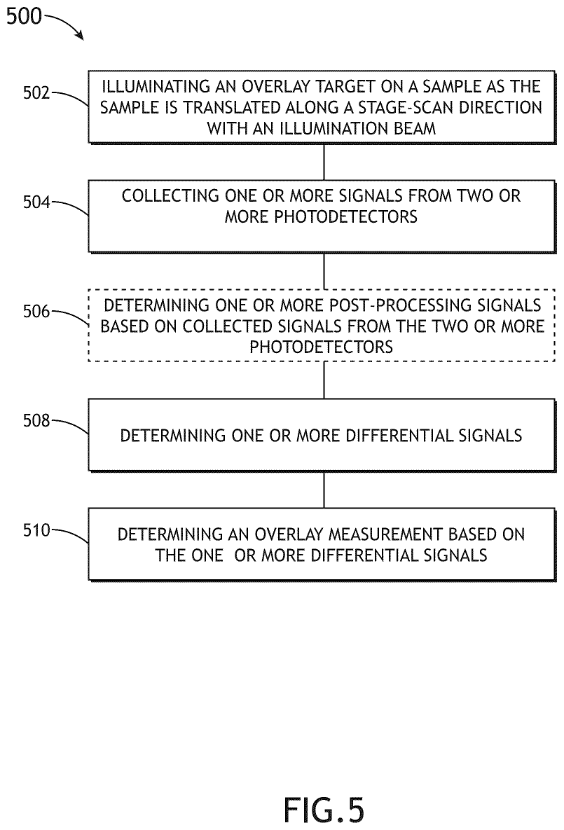

FIG. 5 illustrates a flow diagram illustrating a method 500 for performing scanning DBO scatterometry metrology in accordance with one or more embodiments of the present disclosure. Applicant notes that the embodiments and enabling technologies described previously herein in the context of the system 100 should be interpreted to extend to the method 500. It is further noted, however, that the method 500 is not limited to the architecture of the system 100.

In embodiments, the method 500 includes a step 502 of illuminating an overlay target with one or more cells on a sample having grating-over-grating structures as the sample is translated along a stage-scan direction with an illumination beam, where the first-order diffraction is only captured.

In embodiments, the method 500 includes a step 504 of collecting signals from two photodetectors placed to collect only the first-order diffraction in the collection pupil. For example, in a non-limiting example, four signals may be acquired. For instance, a first signal (S₁) of the first cell associated with +1-order diffraction 308 may be collected by the first photodetector 112a, a second signal (S₂) of the first cell associated with −1-order diffraction 310 may be collected by the second photodetector 112b, a third signal (S₃) of the second cell associated with +1-order diffraction 308 may be collected by the first photodetector 112a, and a fourth signal (S₄) of the second cell associated with −1-order diffraction 310 may be collected by the second photodetector 112b.

In embodiments, the method 500 includes an optional step 506 of generating one or more post-processing signals. For example, where the respective signal collected by the photodetector is oscillating over a period of time, the controller 122 may determine one or more post-processing signals corresponding to the selected ROI 412 (as shown in FIG. 4B). For instance, one or more data processing models (or algorithms) may be applied to the one or more signals (S₁-S₄) corresponding to the ROI 412. It is contemplated herein that the one or more data processing steps may include any type of data processing step including, but not limited to, determining an average signal, weighted average signal, running average signal, or the like.

In embodiment, the method 500 includes a step 508 of determining one or more differential signals between the two photodetectors for each cell of the plurality of cells. For example, as previously discussed herein, differential signals for each cell may be determined using Eq. (1.1)-(1.2) described above.

In embodiments, the method 500 includes a step 510 of determining an overlay measurement based on the differential signals from the two photodetectors. For example, as previously discussed herein, overlay may be determined using at least one of Eqs. (2.1) or (2.2) described above.

It is contemplated herein that the method 500 may be applied to a wide variety of overlay target designs suitable for 1 D or 2D metrology measurements. In embodiments, the method 500 includes simultaneously scanning multiple illumination beams and collecting the associated diffraction orders for parallel measurements. In embodiments, the method 500 includes scanning one or more illumination beams along a beam-scan direction different than the stage-scan direction. In this regard, cells having grating-over-grating structures with different directions of periodicity may be efficiently interrogated by a common illumination beam in a measurement swath.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An overlay metrology system comprising:
an illumination sub-system comprising:
one or more illumination sources configured to generate one or more illumination beams; and
one or more illumination optics configured to direct the one or more illumination beams to an overlay target on a sample as the sample is scanned along a stage-scan direction by a translation stage when implementing a metrology recipe, wherein the overlay target in accordance with the metrology recipe includes a plurality of measurement cells, wherein each measurement cell includes a grating-over-grating structure including a first-layer grating feature on a first layer of the sample and a second-layer grating feature on a second layer of the sample in an overlapping region, wherein the first-layer grating feature and the second-layer grating feature have a common pitch;
a collection sub-system comprising:
a first photodetector located in a pupil plane to collect +1-order diffraction from the overlay target, wherein the first photodetector does not collect 0-order diffraction from the overlay target;
a second photodetector located in a pupil plane to collect −1-order diffraction from the overlay target, wherein the second photodetector does not collect 0-order diffraction from the overlay target; and
one or more collection optics; and
a controller communicatively coupled to the first photodetector and the second photodetector, the controller including one or more processors configured to execute program instructions causing the one or more processors to:
receive one or more signals from the first photodetector and the second photodetector as the overlay target is scanned along the stage-scan direction;
determine one or more differential signals between the first photodetector and the second photodetector for each measurement cell of the plurality of measurement cells based on the received one or more signals; and
determine an overlay measurement based on the determined one or more differential signals.

2. The overlay metrology system of claim 1, wherein the controller is further configured to:
apply one or more data processing models to determine one or more post-processing signals for each of the first photodetector and the second photodetector based on the received one or more signals,
wherein the one or more differential signals between the first photodetector and the second photodetector for each measurement cell of the plurality of measurement cells is determined based on the determined one or more post-processing signals.

3. The overlay metrology system of claim 1, wherein a first differential signal between the first photodetector and the second photodetector for a first measurement cell of the plurality of measurement cells is determined by:
$${D}_{1} = {S}_{1} - {S}_{2} ,$$
where S₁ is a first signal associated with the +1-order diffraction from the overlay target of the first measurement cell from the first photodetector and S₂ is a second signal associated with the −1-order diffraction from the overlay target of the first measurement cell from the second photodetector.

4. The overlay metrology system of claim 3, wherein a second differential signal between the first photodetector and the second photodetector for a second measurement cell of the plurality of measurement cells is determined by:
$${D}_{2} = {S}_{3} - {S}_{4} ,$$
where S₃ is a third signal associated with the +1-order diffraction from the overlay target of the second measurement cell from the first photodetector and S₄ is a fourth signal associated with the −1-order diffraction from the overlay target of the second measurement cell from the second photodetector.

5. The overlay metrology system of claim 4, wherein the overlay measurement based on the determined first differential signal for the first measurement cell and the determined second differential signal for the second measurement cell is determined by:
$$OVL = + {f}_{0} \frac{D 1 + D 2}{D 1 - D 2} ,$$
where +f0 is an intended offset of the first measurement cell.

6. The overlay metrology system of claim 4, wherein the overlay measurement based on the determined first differential signal for the first measurement cell and the determined second differential signal for the second measurement cell is determined by:
$$OVL = \frac{P}{2 π} arctan ( \frac{{D}_{1} + {D}_{2}}{{D}_{1} - {D}_{2}} tan ( \frac{2 π}{P} {f}_{0} ) ) ,$$
where f0 is an intended offset of the first measurement cell, P is a pitch of the first-layer grating feature and the second-layer grating feature.

7. The overlay metrology system of claim 1, further comprising:
a translation stage to translate the sample along the stage-scan direction, wherein the one or more illumination optics direct the one or more illumination beams to the overlay target on the sample as the sample is scanned by the translation stage.

8. The overlay metrology system of claim 1, further comprising:
one or more beam-scanning optics to scan the one or more illumination beams along the stage-scan direction.

9. An overlay metrology system comprising:
a controller communicatively coupled to a first photodetector and a second photodetector, the controller including one or more processors configured to execute program instructions causing the one or more processors to:
receive one or more signals from the first photodetector and the second photodetector as an overlay target is scanned along a stage-scan direction by a translation stage when implementing a metrology recipe, wherein the overlay target in accordance with the metrology recipe includes a plurality of measurement cells, wherein each measurement cell includes a grating-over-grating structure including a first-layer grating feature on a first layer of a sample and a second-layer grating feature on a second layer of the sample in an overlapping region, wherein the first-layer grating feature and the second-layer grating feature have a common pitch;
determine one or more differential signals between the first photodetector and the second photodetector for each measurement cell of the plurality of measurement cells based on the received one or more signals; and
determine an overlay measurement based on the determined one or more differential signals.

10. The overlay metrology system of claim 9, wherein the controller is further configured to:
apply one or more data processing models to determine one or more post-processing signals for each of the first photodetector and the second photodetector based on the received one or more signals,
wherein the one or more differential signals between the first photodetector and the second photodetector for each measurement cell of the plurality of measurement cells is determined based on the determined one or more post-processing signals.

11. The overlay metrology system of claim 9, wherein a first differential signal between the first photodetector and the second photodetector for a first measurement cell of the plurality of measurement cells is determined by:
$${D}_{1} = {S}_{1} - {S}_{2} ,$$
where S₁ is a first signal associated with +1-order diffraction from the overlay target of the first measurement cell from the first photodetector and S₂ is a second signal associated with −1-order diffraction from the overlay target of the first measurement cell from the second photodetector.

12. The overlay metrology system of claim 11, wherein a second differential signal between the first photodetector and the second photodetector for a second measurement cell of the plurality of measurement cells is determined by:
$${D}_{2} = {S}_{3} - {S}_{4} ,$$
where S₃ is a third signal associated with the +1-order diffraction from the overlay target of the second measurement cell from the first photodetector and S₄ is a fourth signal associated with the −1-order diffraction from the overlay target of the second measurement cell from the second photodetector.

13. The overlay metrology system of claim 12, wherein the overlay measurement based on the determined first differential signal for the first measurement cell and the determined second differential signal for the second measurement cell is determined by:
$$OVL = + {f}_{0} \frac{D 1 + D 2}{D 1 - D 2} ,$$
where +f0 is an intended offset of the first measurement cell.

14. The overlay metrology system of claim 12, wherein the overlay measurement based on the determined first differential signal for the first measurement cell and the determined second differential signal for the second measurement cell is determined by:
$$OVL = \frac{P}{2 π} arctan ( \frac{{D}_{1} + {D}_{2}}{{D}_{1} - {D}_{2}} tan ( \frac{2 π}{P} {f}_{0} ) ) ,$$
where f0 is an intended offset of the first measurement cell, P is a pitch of the first-layer grating feature and the second-layer grating feature.

15. A method comprising:
illuminating an overlay target with a plurality of measurement cells on a sample having grating-over-grating structures as the sample is translated along a stage-scan direction with an illumination beam;
receiving one or more signals from a first photodetector and a second photodetector as the overlay target is scanned along the stage-scan direction by a translation stage when implementing a metrology recipe, wherein the overlay target in accordance with the metrology recipe includes a plurality of measurement cells, wherein each measurement cell includes the grating-over-grating structures including a first-layer grating feature on a first layer of the sample and a second-layer grating feature on a second layer of the sample in an overlapping region, wherein the first-layer grating feature and the second-layer grating feature have a common pitch;
determining one or more differential signals between the first photodetector and the second photodetector for each measurement cell of the plurality of measurement cells based on the received one or more signals; and
determining an overlay measurement based on the determined one or more differential signals.

16. The method of claim 15, further comprising:
applying one or more data processing models to determine one or more post-processing signals for each of the first photodetector and the second photodetector based on the received one or more signals,
wherein the one or more differential signals between the first photodetector and the second photodetector for each measurement cell of the plurality of measurement cells is determined based on the determined one or more post-processing signals.

17. The method of claim 15, wherein a first differential signal between the first photodetector and the second photodetector for a first measurement cell of the plurality of measurement cells is determined by:
$${D}_{1} = {S}_{1} - {S}_{2} ,$$
where S₁ is a first signal associated with +1-order diffraction from the overlay target of the first measurement cell from the first photodetector and S₂ is a second signal associated with −1-order diffraction from the overlay target of the first measurement cell from the second photodetector.

18. The method of claim 17, wherein a second differential signal between the first photodetector and the second photodetector for a second measurement cell of the plurality of measurement cells is determined by:
$${D}_{2} = {S}_{3} - {S}_{4} ,$$
where S₃ is a third signal associated with the +1-order diffraction from the overlay target of the second measurement cell from the first photodetector and S₄ is a fourth signal associated with the −1-order diffraction from the overlay target of the second measurement cell from the second photodetector.

19. The method of claim 18, wherein the overlay measurement based on the determined first differential signal for the first measurement cell and the determined second differential signal for the second measurement cell is determined by:
$$OVL = + {f}_{0} \frac{D 1 + D 2}{D 1 - D 2} ,$$
where +f0 is an intended offset of the first measurement cell.

20. The method of claim 18, wherein the overlay measurement based on the determined first differential signal for the first measurement cell and the determined second differential signal for the second measurement cell is determined by:
$$OVL = \frac{P}{2 π} arctan ( \frac{{D}_{1} + {D}_{2}}{{D}_{1} - {D}_{2}} tan ( \frac{2 π}{P} {f}_{0} ) ) ,$$
where f0 is an intended offset of the first measurement cell, P is a pitch of the first-layer grating feature and the second-layer grating feature.
